(19) United States
(12) Patent Application Publication
(10) Pub. No.: US 2012/0106246 A1
(43) Pub. Date: May 3, 2012

(54) NON-VOLATILE SEMICONDUCTOR MEMORY DEVICE, METHOD OF WRITING THE SAME, AND SEMICONDUCTOR DEVICE

(75) Inventor: Hidefumi NAWATA, Kawasaki-shi (JP)

(73) Assignee: Kabushiki Kaisha Toshiba, Tokyo (JP)

(21) Appl. No.: 13/052,180

(22) Filed: Mar. 21, 2011

(30) Foreign Application Priority Data
Oct. 27, 2010 (JP) 2010-240387

(51) Int. Cl. G11C 16/10; G11C 16/04

(52) U.S. Cl. 365/185.03; 365/185.24

(57) ABSTRACT

A control circuit is configured to be able to perform a rough write process, a foggy write process, and a fine write process. The rough write process moves, for a memory cell to be provided with a plurality of second threshold voltage distributions, a first threshold voltage distribution in the positive direction to generate a third threshold voltage distribution. The foggy write process does not move, for a memory cell finally to be provided with first data, the third threshold voltage distribution, and moves, for a memory cell finally to be provided with second data different from the first data, the first threshold voltage distribution or the third threshold voltage distribution in the positive direction to generate a plurality of fourth threshold voltage distributions. The fine write process moves the fourth threshold voltage distributions in the positive direction to generate the second threshold voltage distributions.

### CROSS-REFERENCE TO RELATED APPLICATIONS

This application is based upon and claims the benefit of priority from the prior Japanese Patent Application No. 2010-240387, filed on Oct. 27, 2010, the entire contents of which are incorporated herein by reference.

### FIELD

The embodiments described herein relate to an electrically rewritable non-volatile semiconductor memory device, a method of writing the same, and a semiconductor device.

### BACKGROUND

A NAND flash memory is in increasing demand with an increase of applications that handle a large volume of data such as image or moving image in a mobile device or the like. More particularly, adoption of the multi-level storage technology that may store two-bit or more information in one memory cell allows a small chip area to store more information.

There is a problem with a highly integrated flash memory containing much smaller cells that an interference between adjacent cells spreads the width of the threshold voltage distribution (the width between the upper limit and the lower limit of one threshold voltage distribution). More particularly, the multi-level storage scheme needs to set, compared to the binary storage scheme, a smaller interval between the upper limit of a threshold voltage distribution and the lower limit of another threshold voltage distribution. The interference between adjacent cells thus largely affects the data reliability.

### BRIEF DESCRIPTION OF THE DRAWINGS

FIG. 1 a block diagram of a schematic configuration of a non-volatile semiconductor memory device (NAND cell flash memory) according to a first embodiment;

FIG. 2 is a circuit diagram of the configuration of a memory cell array 1 shown in FIG. 1;

FIG. 3 is a schematic diagram of the write process of a non-volatile semiconductor memory device according to the first embodiment;

FIG. 4 shows the writing sequence of a non-volatile semiconductor memory device according to the first embodiment;

FIG. 5 is a schematic diagram of the write process of a non-volatile semiconductor memory device according to a second embodiment;

FIG. 6 shows the writing sequence of a non-volatile semiconductor memory device according to the second embodiment;

FIG. 7 is a schematic diagram of the write process of a non-volatile semiconductor memory device according to a third embodiment; and

FIG. 8 shows the writing sequence of a non-volatile semiconductor memory device according to the third embodiment.

### DETAILED DESCRIPTION

A non-volatile semiconductor memory device according to an aspect includes a memory cell array including a plurality of memory cells and a control circuit for controlling the memory cell. The memory cell is configured to be able to store data using a first threshold voltage distribution and a plurality of second threshold voltage distributions. The first threshold voltage distribution has a negative upper limit and represents the erased state. The second threshold voltage distributions each have a lower limit higher than the upper limit of the first threshold voltage distribution and represent the written state. The control circuit is configured to perform a rough write process, a foggy write process, and a fine write process. The rough write process moves, for a memory cell to be provided with the second threshold voltage distributions, the first threshold voltage distribution in the positive direction to generate a third threshold voltage distribution. The foggy write process does not move, for a memory cell finally to be provided with first data, the third threshold voltage distribution and moves, for a memory cell finally to be provided with the first data, the first threshold voltage distribution or the third threshold voltage distribution in the positive direction to generate a plurality of fourth threshold voltage distributions. The fine write process moves the fourth threshold voltage distributions in the positive direction to generate the second. threshold voltage distributions.

Referring now to the drawings, non-volatile. semiconductor memory devices according to embodiments will be described.

### First Embodiment

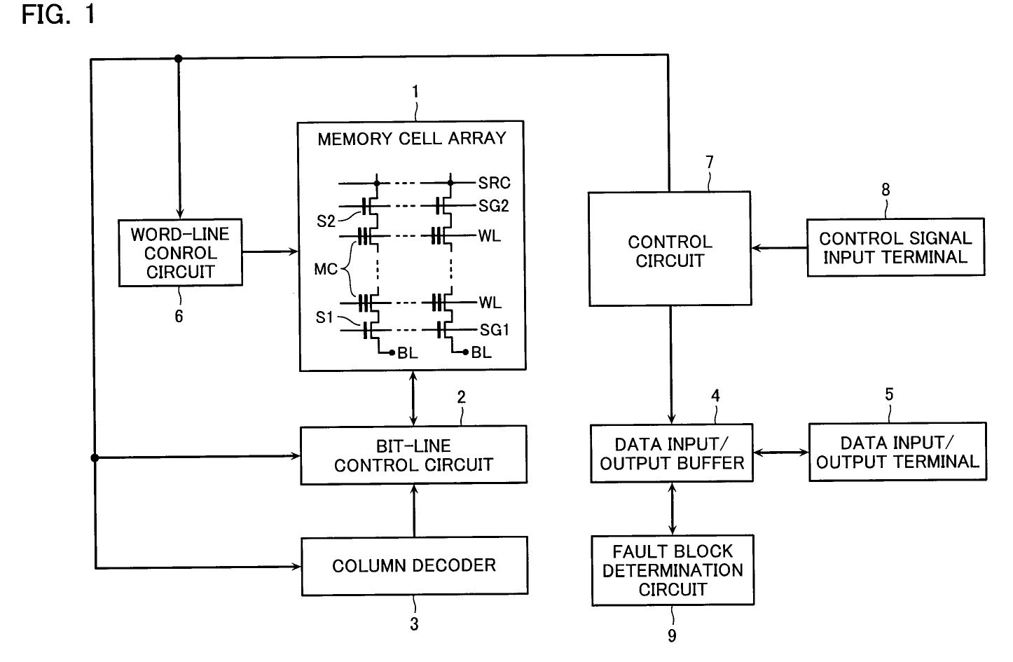

FIG. 1 shows the configuration of a non-volatile semiconductor memory device (four-level write NAND cell flash memory) adopting the four-level storage scheme according to a first embodiment. The non-volatile semiconductor memory device includes a memory cell array 1. The array 1 includes memory cells MC for storing data. The memory cells MC are arranged in a matrix. The memory cell array 1 includes a plurality of bit-lines BL, a plurality of word-lines WL, a source-line SRC, and a plurality of memory cells MC. The memory cells MC are configured to be able to electrically rewrite data. The cells MC are arranged in a matrix at the intersections of the bit-lines BL and the word-lines WL.

To the memory cell array 1, a bit-line control circuit 2 for controlling the voltage of a bit-line BL, and a word-line control circuit 6 for controlling the voltage of a word-line WL are connected. Specifically, the bit-line control circuit 2 reads data of a memory cell MC in the memory cell array 1 via the bit-line BL, while the circuit 2 applies a control voltage to a memory cell MC in the memory cell array 1 via the bit-line BL to write data in the memory cell MC.

The bit-line control circuit 2 is connected to a column decoder 3, a data input/output buffer 4, and an data input/output terminal 5. Data of a memory cell 14C read from the memory cell array 1 is output externally via the data input/output terminal 5. Write data externally input to the data input/output terminal 5 is directed by the column decoder 3 to the bit-line control circuit 2. The data is thus written to an assigned memory cell MC.

The memory cell array 1, the bit-line control circuit 2, the column decoder 3, the data input/output buffer 4, and the word-line control circuit 6 are also connected to a control circuit 7. The control circuit 7 generates, according to a control signal input to a control signal input terminal 8, a control signal for controlling the memory cell array 1, the bit-line control circuit 2, the column decoder 3, the data input/output buffer 4, and the word-line control circuit 6. The data input/output buffer 4 is connected to a fault block determination circuit 9 that determines, according to read data, whether a block to be read is a fault block.

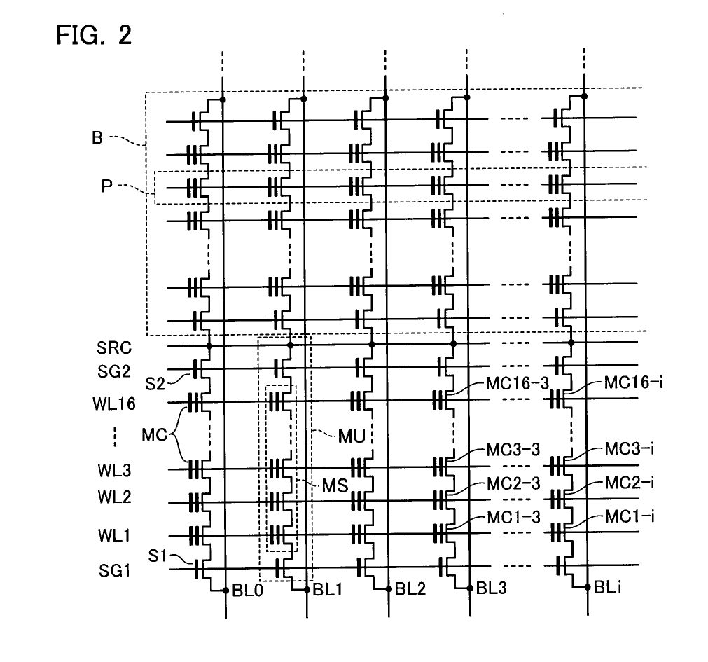

FIG. 2 shows the configuration of the memory cell array 1 shown in FIG. 1. The memory cell array 1 includes, as shown in FIG. 2, a plurality of blocks B. In the memory cell array 1, data is erased in units of blocks B.

Each block B includes, as shown in FIG. 2, a plurality of memory units MU. One memory unit MU includes a memory string MS. The memory string MS includes, for example, 16 memory cells MC (EEPROM) connected in series. The memory unit MU also includes first and second select transistors S1 and S2 connected at the ends of the memory string MS, respectively. The first select transistor S1 has an end connected to the bit-line BL0. The second select transistor S2 has an end connected to the source-line SRC. The control gates of the memory cells MC are aligned in the row direction and are commonly connected to one of the word-lines WL1 to WL16. The control gates of the first select transistor S1 are aligned in the row direction and are commonly connected to the select line SG1. The control gates of the second select transistor S2 are aligned in the row direction and are commonly connected to the select line SG2.

A set P of the memory cells MC connected to one word-line WL forms one page or a plurality of pages. Data is written or read for each set P.

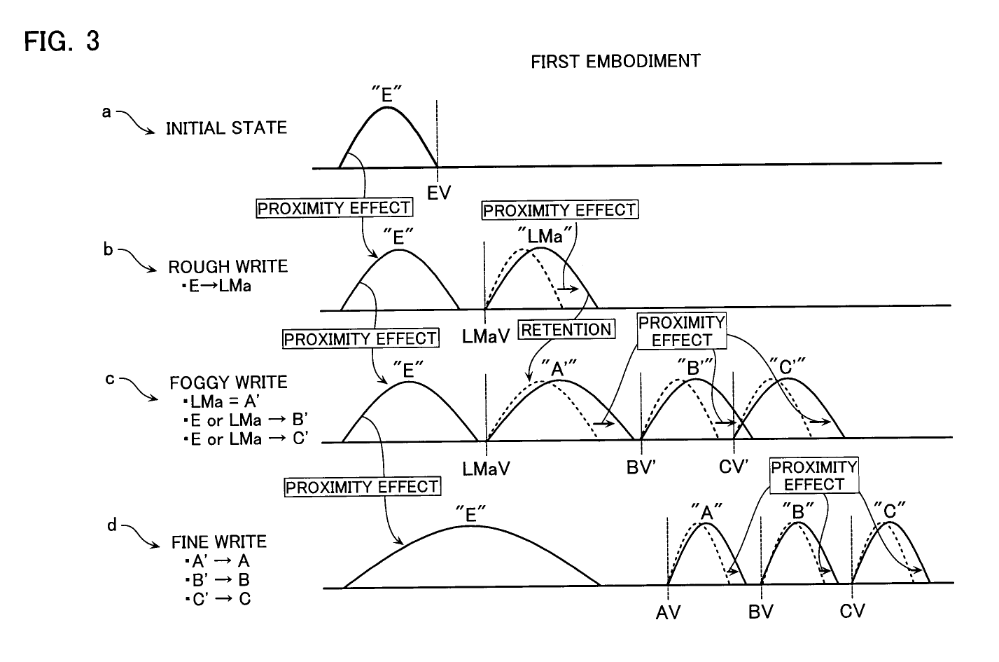

Referring now to FIG. 3, the four-level storage write process according to the first embodiment will be described. The non-volatile semiconductor memory device is configured to allow each memory cell MC to have a threshold voltage of four types of threshold voltage distributions. Specifically, the memory cell MC is configured to be able to store four-level data. As shown in FIG. 3“a” to “d”, from a threshold voltage distribution E (first threshold voltage distribution) showing the erased state, the control circuit 7 finally provides threshold voltage distributions A, B, and C (second threshold voltage distributions) (E<A<B<C). For example, the threshold voltage distributions E, A, B, and C show respective data “11,” “01,” “10,” and “00.”

In the first embodiment, the control circuit 7 writes data in three stages as shown in FIG. 3: the rough write process as coarse writing (FIG. 3“b”); the foggy write process (FIG. 3“c”); and the fine write process as accurate writing (FIG. 3“d”). The control circuit 7 may thus reduce the width spread of the threshold voltage distribution due to the interference between adjacent cells compared to when writing data in one or two stages.

In the non-volatile semiconductor memory device according to this embodiment, data for each page is written at once. There are a memory cell MC (write memory cell) that needs to move the threshold voltage distribution and a memory cell MC (non-write memory cell) that does not need to move the threshold voltage distribution in one page. For example, therefore, by providing the bit-line BL connected to the write memory cell with a voltage of 0V, and providing the bit-line BL connected with the non-write memory cell to the power supply voltage Vdd, data for each page may be written at once.

First, from the initial state (FIG. 3“a”), the control circuit 7 performs the rough write process (FIG. 3“b”). In the initial state, all memory cells MC are in an erased state, and provided with the threshold voltage distribution E (first threshold voltage distribution). The rough write process shown in FIG. 3“b” moves, for the memory cell MC to be provided with one of the final threshold voltage distributions A, B, and C (second threshold voltage distributions), the threshold voltage distribution E in the positive direction. Then, as the lower limit of the threshold voltage distribution, a verify voltage LMaV is used to generate a threshold voltage distribution LMa (third threshold voltage distribution) (E<LMa).

The verify voltage LMaV is higher than a verify voltage EV approximately equal to the upper limit of the threshold voltage distribution E. Note that after the rough write process to a memory cell, writing to an adjacent memory cell causes an interference effect (proximity effect) from the adjacent cell. The effect spreads the widths of the threshold voltage distributions E and LMa compared to before writing to the adjacent memory cell.

The control circuit 7 then performs the foggy write process (FIG. 3“c”). The foggy write process is a write process that generates threshold voltage distributions A′, B′, and C′ (fourth threshold voltage distributions) according to the threshold voltage distributions E (first threshold voltage distribution) and the LMa (third threshold voltage distribution) obtained based on the rough write process. The threshold voltage distributions A′, B′, and C′ are lower than the respective final threshold voltage distributions A, B, and C (second threshold voltage distribution). With reference to FIG. 3“c”, the foggy write process treats the memory cell MC finally to be provided with the threshold voltage distribution A as the non-write memory cell. Specifically, the potential of the bit-line BL is set to the same state (for example, the power supply voltage Vdd) as the threshold voltage distribution E. As a result, the threshold of the memory cell MC finally to be provided with the threshold voltage distribution A does not increase but remains at the threshold voltage distribution LMa. The foggy write process sets, for the memory cell MC finally to be provided with the threshold voltage distributions B or C, the potential of the bit-line BL at, for example, 0V to increase the threshold of the memory cell MC. In adjusting the lower limit of the threshold of the memory cell MC, verify voltages BV′ and CV′ different from the verify voltage LMaV, respectively, are used to generate the threshold voltage distributions B′ and C′ (LMaV<BV′<CV′). Note that after the foggy writing to a memory cell, writing to an adjacent memory cell causes an interference effect (proximity effect) from adjacent memory cell. The effect spreads the widths of the threshold voltage distributions E, A′, B′, and C′ compared to before writing to the adjacent memory cell. The threshold voltage distributions E, A′, B′, and C′ thus overlap to each other. Even if the threshold voltage distributions E, A′, B′, and C′ overlap to each other, data corresponding to the respective threshold voltage distributions may be temporarily stored to determine the threshold voltage distributions E, A′, B′, and C′.

After the foggy write process, the control circuit 7 performs the fine write process (FIG. 3“d”). With reference to FIG. 3“d”, the fine write process moves the threshold voltage distributions A′, B′, and C′ in the positive direction, and uses verify voltages AV, BV, and CV (AV<BV<CV) generally equal to the respective lower limits of the threshold voltage distributions A, B, and C to generate the threshold voltage distributions A, B, and C. As described above, in the first embodiment, generating the threshold voltage distribution B or C requires three write processes (E→LMa→B′→B, E→LMa→>C′→C), while generating the threshold voltage distribution A requires only two write processes (E→LMa (A′)→A).

After the fine write process, the interference (proximity effect) between adjacent cells somewhat varies the threshold voltage distributions E, A, B, and C (FIG. 3“d”). The writing procedure or the like may be optimized to decrease the variation.

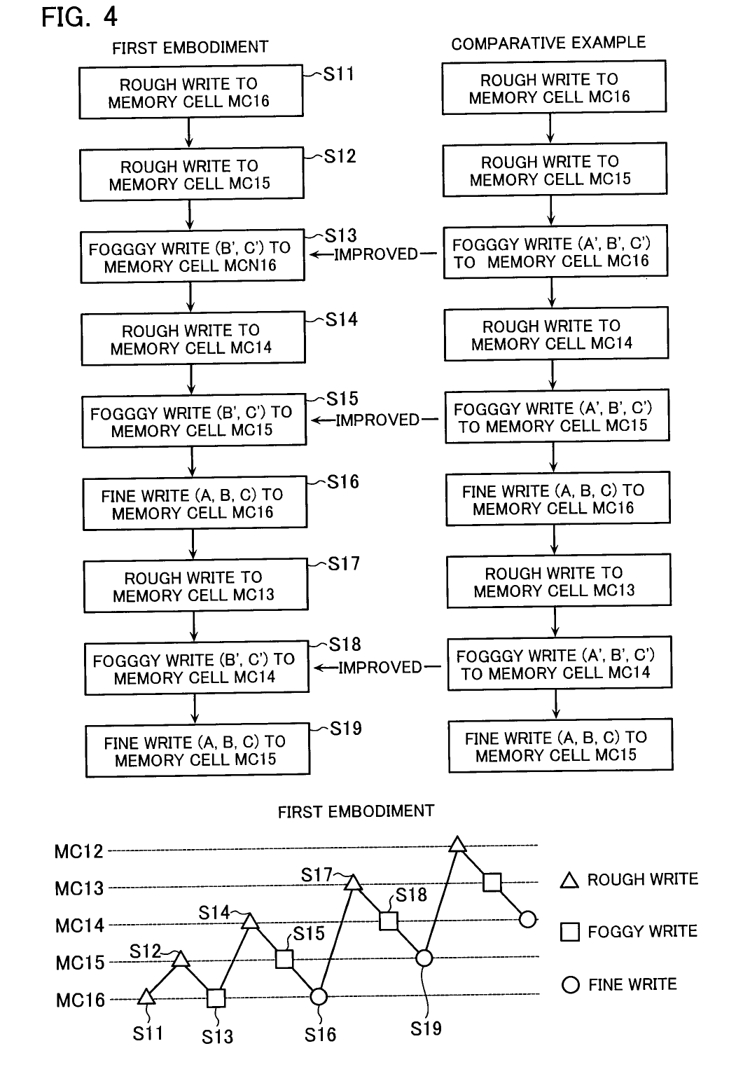

Referring now to FIG. 4, an example writing procedure for decreasing the variation of the threshold voltage distribution will be described. For convenience, memory cells MC1-0, MC1-1, MC1-2, . . . , and MC1-i commonly connected to the word-line WL1 are generally referred to as a memory cell MC1. Memory cells MC2-0, MC2-1, MC2-2, . . . , and MC2-i commonly connected the word-line WL2 are generally referred to as a memory cell MC2. Likewise, memory cells MC16-0, MC16-1, MC16-2, . . . , and MC16-i commonly connected to the word-line WL16 are generally referred to as a memory cell MC16. The memory cell MC16 nearest the source-line SRC is written first, and then the other memory cells are written in sequence. The memory cell MC1 farthest from the source-line SRC is written finally (see FIG. 2).

In providing the memory cells MC with the foggy write process and the fine write process, the writing procedure as shown in FIG. 4 may be performed to minimize the variation of the threshold voltage distribution. Note that the foggy write processes at steps S13, S15, and S19 as described below, do not move, like the process shown in FIG. 3, the threshold voltage distribution LMa after the rough write process, thereby generating the one of the threshold voltages A′, B′, and C′ that has the lowest threshold voltage, that is the threshold voltage distribution A′.

In the first embodiment, as shown in FIG. 4, first, the rough write process is performed to a memory cell MC16 (step S11), and then the rough write process is performed to a memory cell MC15 adjacent to the memory cell MC16 (nearer to the bit-line BL by one memory cell) (step S12). The proximity effect due to the rough write process performed to the memory cell MC15 varies the threshold voltage distribution of the memory cell MC16 after the rough write process to it.

The foggy write process is then performed to the memory cell MC16 (step S13). The rough write process is then performed to a memory cell MC14 (step S14). The cell MC14 is nearer to the bit-line BL by two memory cells than the memory cell MC16. The foggy write process is then performed to the memory cell MC15 (step S15). The rough write process to the memory cell MC14 and the foggy write process to the memory cell MC15 vary the threshold voltage distribution of the memory cell MC16 after the foggy write process to it.

The fine write process is then performed to the memory cell MC16 (step S16). The foggy write process at step S15 treats the memory cell MC finally to be provided with the threshold voltage distribution A as the non-write memory cell. As a result, the threshold voltage distribution LMa of the memory cell MC finally to be provided with the threshold voltage distribution A does not move in the positive direction. Compared to the conventional foggy write, therefore, the foggy write process to the memory cell MC15 provides less proximity effect to the memory cell MC16. As a result, the fine write process may effectively decrease the affect of the proximity effect from the adjacent memory cell.

After step S16, the rough write process is performed to a memory cell MC13 three cells away from the memory cell MC16 in which the fine write process is completed (step S17). The rough write process to the memory cell MC13 provides less proximity effect to the memory cell MC16 because the memory cell MC13 and the memory cell MC16 are three memory cells away from each other. This may thus minimize the variation of the threshold voltage distribution of the memory cell MC16 after the fine write process to it.

The foggy write process is then performed to a memory cell MC14 (step S18). The memory cell MC14 is two memory cells

MC away from the memory cell MC16. The foggy write process in this embodiment treats the memory cell MC finally to be provided with the threshold voltage distribution A as the non-write memory cell. As a result, the threshold voltage distribution LMa of the memory cell MC finally to be provided with the threshold voltage distribution A does not move in the positive direction. Compared to the conventional foggy write, therefore, the foggy write process to the memory cell MC14 provides less proximity effect to the memory cell MC16.

The fine write process is then performed to the memory cell MC15 (step S19).

In this way, the rough write process and the foggy write process to the memory cell MC15 are performed before the fine write process to the memory cell MC16. The processes to the memory cell MC15 will thus give little affect to the width of the threshold voltage distribution that the memory cell MC16 will finally have. The threshold voltage distribution of the memory cell MC16 after the fine write process to it is varied only by the fine write operation to the adjacent memory cell MC15 and the foggy write operation to the two-cell-away memory cell MC14.

The rough write process is then performed to the memory cell MCn+3 three cells away in the direction of the bit-line BL from the memory cell MCn (n is a natural number) in which the fine write is completed. The foggy write process is then performed to the memory cell MCn+2 in which the rough write process is completed. The fine write process is then performed to the memory cell MCn+1 in which the foggy write process is completed. The above procedure is repeated. The memory cell array 1 that is subject to the rough/foggy/fine write processes may thus receive the least affect from the adjacent memory cell MC.

Consider now a comparative example. In this comparative example, the threshold voltage distribution LMa is moved in the positive direction in a foggy write operation, unlike in the first embodiment. That is, three new threshold voltage distributions A′, B′, and C′ that are different from the threshold voltage distribution LMa after a rough write process is generated in a foggy write process. In the comparative example, generation of each of the threshold voltage distributions A, B, and C requires three write processes (E→LMa→A→A, E→LMa→B′→B, and E→LMa→C′→C), respectively.

In contrast, the first embodiment generates, in the foggy write processes at steps S13, S15 and S18, the threshold voltage distribution A′ by not moving the threshold voltage distribution LMa after the rough write process. Therefore, the generation of the threshold voltage distribution B or C, requires three write processes (E→LMa→B′→B, and E→LMa→C′→C), while the generation of the threshold voltage distribution A only requires two write processes (E→LMa (A′)→A). Specifically, in the first embodiment, the threshold voltage distribution A may be generated with one write process less than the comparative example (the verify voltage A′ in the comparative example is omitted). The first embodiment, therefore, may provide a higher write speed and a less interference between adjacent cells than the comparative example.

### Second Embodiment

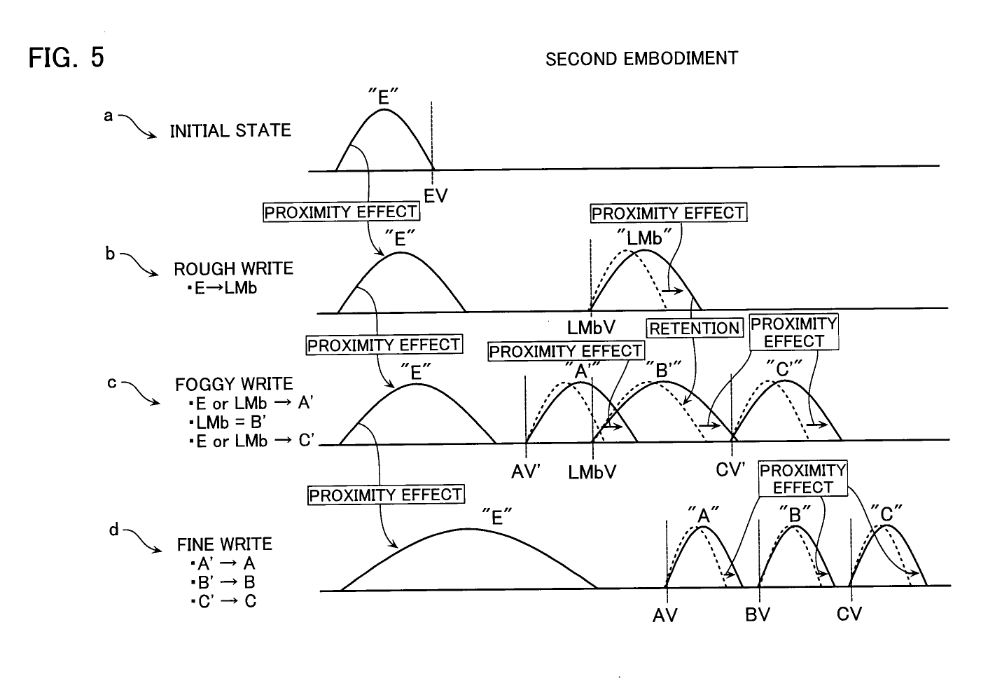

A non-volatile semiconductor memory device according to a second embodiment will now be described. The second embodiment has a similar configuration to the first embodiment, while it has a different write scheme from the first embodiment. With reference to FIG. 5, a non-volatile semiconductor memory device according to the second embodiment write process will be described below.

In the second embodiment, the rough write process as shown in FIG. 5“b” uses a verify voltage LMbV higher than the verify voltage LMaV in the first embodiment to move the threshold voltage distribution E in the positive direction to generate a threshold voltage distribution LMb (LMa<LMb). In this regard, the second embodiment is different from the first embodiment. Note that after the rough write process, an interference between adjacent cells occurs, thereby spreading the widths of the threshold voltage distributions E and LMb.

The foggy write process as shown in FIG. 5“c” treats the memory cell MC finally to be provided with the threshold voltage distribution B as the non-write memory cell. As a result, the threshold voltage distribution LMb of the memory cell MC finally to be provided with the threshold voltage distribution B does not move in the positive direction but provides a threshold voltage distribution B′ (LMb=B′). The foggy write process treats the memory cell MC finally to be provided with the threshold voltage distribution A or C as the write memory cell, and moves the threshold voltage distributions E and LMb in the positive direction to generate the threshold voltage distribution A′ or C′. A verify voltage AV′ or CV′ different from the verify voltage LMbV, respectively, is used to set the lower limit of the threshold voltage distribution E or LMb. The control circuit 7 then performs, like the first embodiment, the fine write process (FIG. 5“d”).

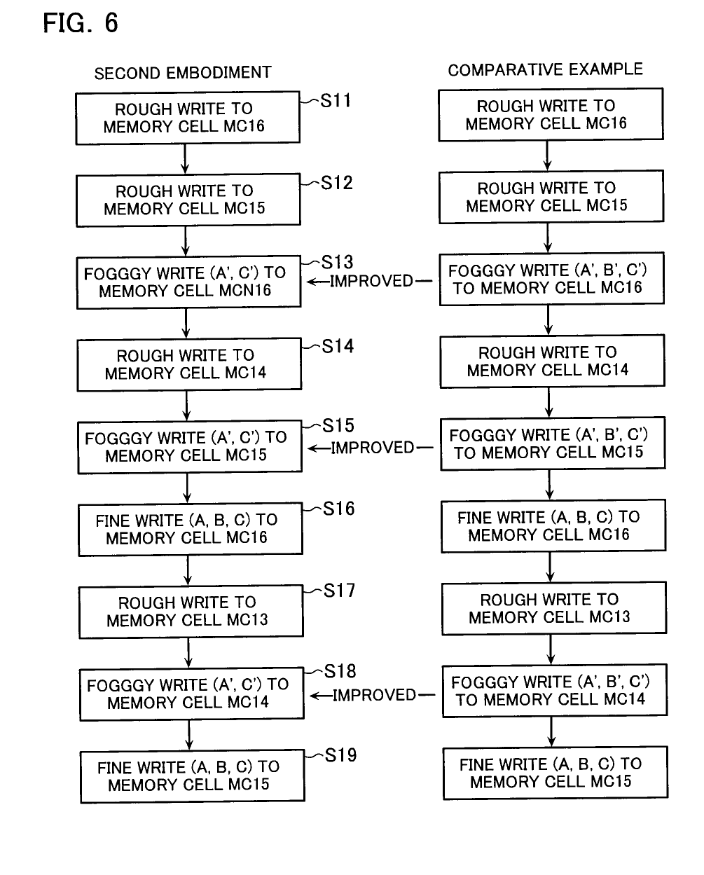

Referring now to FIG. 6, an example writing procedure for decreasing the variation of the threshold voltage distribution will be described. With reference to FIG. 6, the second embodiment performs processes at steps S11 to S19 similar to those in the first embodiment. Note, however, that the second embodiment generates, in the foggy write processes at steps S13, S15, and S18, the threshold voltage distribution B′ by not moving the threshold voltage distribution LMb after the rough write process. Therefore, the generation of the threshold voltage distribution C requires three write processes (E→LMb→C′→C), while the generation of the threshold voltage distribution A or B only requires two write processes (E→A′→A, E→LMb (B′)→B). Specifically, the second embodiment may improve, in the example shown in FIG. 6, the foggy write processes at steps S13, S15 and S18, and provide similar effects to the first embodiment.

### Third Embodiment

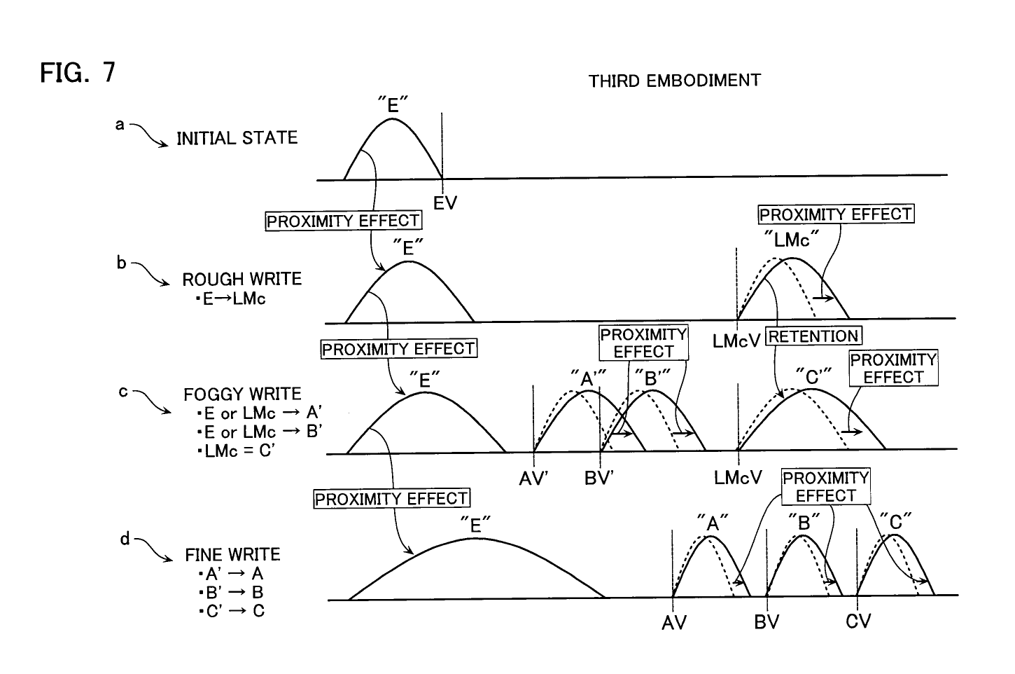

A non-volatile semiconductor memory device according to a third embodiment will now be described. The third embodiment has a similar configuration to the first embodiment, while it has a different write scheme from the first embodiment. With reference to FIG. 7, the write process of the non-volatile semiconductor memory device according to the third embodiment will be described below.

In the third embodiment, the rough write process shown in FIG. 7“b” uses a verify voltage LMcV higher than the verify voltages LMaV and LMbV in the first and second embodiments to move the threshold voltage distribution E in the positive direction to generate a threshold voltage distribution LMc (LMb<LMc). In this regard, the third embodiment is different from the first and second embodiments. Note that after the rough write process, an interference between adjacent cells occurs, thereby spreading the widths of the threshold voltage distributions E and LMc.

The foggy write process as shown in FIG. 7“c” treats the memory cell MC finally to be provided with the threshold voltage distribution C as the non-write memory cell. As a result, the threshold voltage distribution LMb of the memory cell MC finally to be provided with the threshold voltage distribution C does not move in the positive direction but provides a threshold voltage distribution C′ (LMc=C′). The foggy write process treats the memory cell MC finally to be provided with the threshold voltage distribution A or B as the write memory cell, and moves the threshold voltage distribution E in the positive direction to generate the threshold voltage distribution A′ or B′. A verify voltage AV′ or BV′ different from the verify voltage LMcV, respectively, is used to set the lower limit of the threshold voltage distribution E. The control circuit 7 then performs, like the first embodiment, the fine write process (FIG. 7“d”).

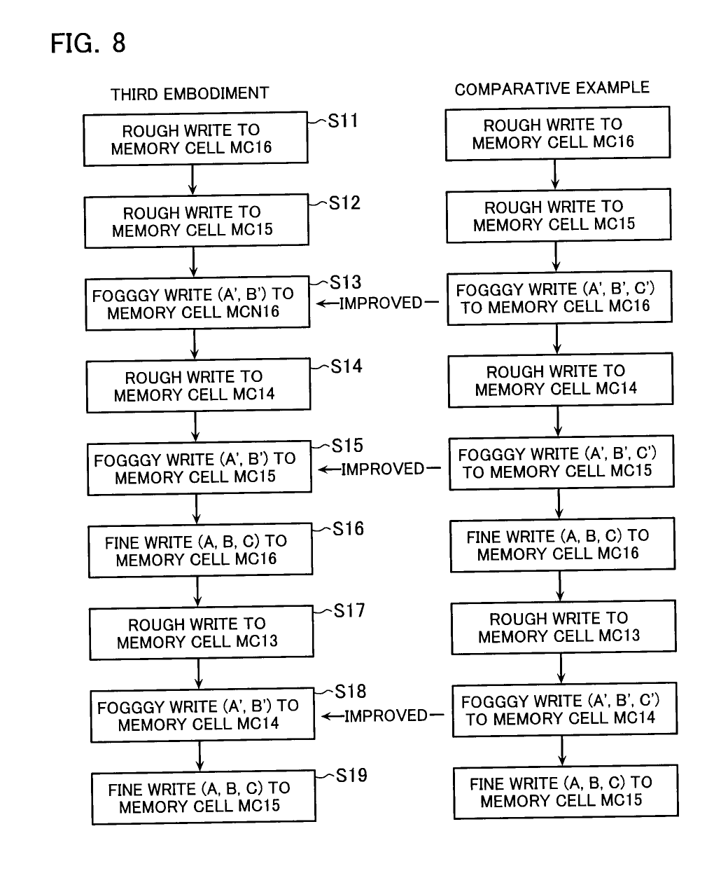

Referring now to FIG. 8, an example writing procedure for decreasing the variation of the threshold voltage distribution will be described. With reference to FIG. 8, the third embodiment performs processes at steps S11 to S19 similar to those in the first embodiment. Note, however, that the third embodiment generates, in the foggy write processes at steps S13, S15, and S18, the threshold voltage distribution C′ by not moving the threshold voltage distribution LMc after the rough write process. Therefore, the generation of the threshold voltage distribution A, B or C only requires two write processes (E→A′→A, E→B′→B, and E→LMc (C′)→C). Specifically, the third embodiment may improve, in the example shown in FIG. 8, the foggy write processes at steps S13, S15 and S18, and provide similar effects to the first embodiment.

### Other Embodiments

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

Although, for example, the above embodiments have been described with respect to the four-level storage scheme (two bits/cell) non-volatile semiconductor device, it will be appreciated that the present invention is not limited to the embodiments, and is also applicable to a more-level storage scheme such as an eight-level storage scheme.

What is claimed is:

1. A non-volatile semiconductor memory device comprising: a memory cell array comprising a plurality of memory cells, each memory cell being configured to be able to store data using a first threshold voltage distribution having a negative upper limit, the first threshold voltage distribution representing an erased state , and a plurality of second threshold voltage distributions, each second threshold voltage distribution having a lower limit higher than the upper limit of the first threshold voltage distribution, each second threshold voltage distribution representing a written state; and
a control circuit being configured to perform:
a rough write process in which for a memory cell to be provided with the second threshold voltage distributions, the first threshold voltage distribution is moved in the positive direction to generate a third threshold voltage distribution;
a foggy write process in which for a memory cell finally to be provided with first data, the third threshold voltage distribution is not moved, and for a memory cell finally to be provided with second data different from the first data, the first threshold voltage distribution or the third threshold voltage distribution is moved in the positive direction to generate a plurality of fourth threshold voltage distributions; and
a fine write process in which the fourth threshold voltage distributions are moved in the positive direction to generate the second threshold voltage distributions.

2. The non-volatile semiconductor memory device according to claim 1, wherein
the control circuit is configured to perform the rough write process to a second memory cell three cells away in a first direction from a first memory cell in which the fine write process is completed, then perform the foggy write process to a third memory cell two cells away in the first direction from the first memory cell and in which the rough write process is completed, and then perform the fine write process to a fourth memory cell one cell away in the first direction from the first memory cell and in which the foggy write process is completed.

3. The non-volatile semiconductor memory device according to claim 1, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate, in the foggy write process, the lowest threshold voltage distribution in the fourth threshold voltage distributions, based on the third threshold voltage distribution.

4. The non-volatile semiconductor memory device according to claim 1, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate the second highest threshold voltage distribution in the fourth threshold voltage distributions, based on the third threshold voltage distribution.

5. The non-volatile semiconductor memory device according to claim 1, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate the highest threshold voltage distribution in the fourth threshold voltage distributions, based on the third threshold voltage distribution.

6. The non-volatile semiconductor memory device according to claim 2, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate, in the foggy write process, the lowest threshold voltage distribution in the fourth threshold voltage distributions, based on the third threshold voltage distribution.

7. The non-volatile semiconductor memory device according to claim 2, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate the second highest threshold voltage distribution in the fourth threshold voltage distributions, based on the third threshold voltage distribution.

8. The non-volatile semiconductor memory device according to claim 2, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate the highest threshold voltage distribution in the fourth threshold voltage distributions, based on the third threshold voltage distribution.

9. The non-volatile semiconductor memory device according to claim 1, wherein
the memory cell array comprises:
a memory string comprising the memory cells connected in series;
a first select transistor connected to a first end of the memory string; and
a second select transistor connected to a second end of the memory string.

10. The non-volatile semiconductor memory device according to claim 9, wherein
the memory string is provided in a plurality, and
the memory cell array comprises a plurality of blocks, the blocks comprising the memory strings, and data being erased in units of blocks.

11. A semiconductor device, comprising a control circuit for controlling a memory cell configured to be able to store data using a first threshold voltage distribution having a negative upper limit, the first threshold voltage distribution representing an erased state, and a plurality of second threshold voltage distributions, each second threshold voltage distribution having a lower limit higher than the upper limit of the first threshold voltage distribution, and each second threshold voltage distribution representing a written state,
the control circuit being configured to perform:
a rough write process in which for a memory cell to be provided with the second threshold voltage distributions, the first threshold voltage distribution is moved in the positive direction to generate a third threshold voltage distribution;
a foggy write process in which for a memory cell finally to be provided with first data, the third threshold voltage distribution is not moved, and for a memory cell finally to be provided with second data different from the first data, the first threshold voltage distribution or the third threshold voltage distribution is moved in the positive direction to generate a plurality of fourth threshold voltage distributions; and
a fine write process in which the fourth threshold voltage distributions are moved in the positive direction to generate the second threshold voltage distributions.

12. The semiconductor device according to claim 11, wherein
the control circuit is configured to perform the rough write process to a second memory cell three cells away in a first direction from the first memory cell in which the fine write process is completed, then perform the foggy write process to a third memory cell two cells away in the first direction from the first memory cell and in which the rough write process is completed, and then perform the fine write process to a fourth memory cell one cell away in the first direction from the first memory cell and in which the foggy write process is completed.

13. The semiconductor device according to claim 11, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate, in the foggy write process, the one of the three fourth threshold voltage distributions that has the lowest threshold voltage distribution based on the third threshold voltage.

14. The semiconductor device according to claim 11, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate the one of the three fourth threshold voltage distributions that has the second highest threshold voltage distribution based on the third threshold voltage distribution.

15. The semiconductor device according to claim 11, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the control circuit is configured to generate the one of the three fourth threshold voltage distributions that has the highest threshold voltage distribution based on the third threshold voltage distribution.

16. A method of writing a non-volatile semiconductor memory device comprising a memory cell array comprising a plurality of memory cells, each memory cell being configured to be able to store data using a first threshold voltage distribution having a negative upper limit, the first threshold voltage distribution representing an erased state, and a plurality of second threshold voltage distributions, each second threshold voltage distribution having a lower limit higher than the upper limit of the first threshold voltage distribution, and each second threshold voltage distribution representing a written state,
the method comprising:
a rough write process for a memory cell to be provided with the second threshold voltage distributions, to move the first threshold voltage distribution in the positive direction to generate a third threshold voltage distribution;
a foggy write process for a memory cell finally to be provided with first data, not to move the third threshold voltage distribution, and for a memory cell finally to be provided with second data different from the first data, to move the first threshold voltage distribution or the third threshold voltage distribution in the positive direction to generate a plurality of fourth threshold voltage distributions; and
a fine write process to move the fourth threshold voltage distributions in the positive direction to generate the second threshold voltage distributions.

17. The method of writing a non-volatile semiconductor memory device according to claim 16, further comprising:
performing the rough write process to a second memory cell three cells away in a first direction from a first memory cell in which the fine write process is completed;
then performing the foggy write process to a third memory cell two cells away in the first direction from the first memory cell and in which the rough write process is completed; and
then performing the fine write process to a fourth memory cell one cell away in the first direction from the first memory cell and in which the foggy write process is completed.

18. The method of writing a non-volatile semiconductor memory device according to claim 16, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the method further comprises generating, in the foggy write process, the lowest threshold voltage distribution in the fourth threshold voltage distributions, based on the third threshold voltage.

19. The method of writing a non-volatile semiconductor memory device according to claim 16, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the method further comprises generating the second highest threshold voltage distribution in the fourth threshold voltage distributions, based on the third threshold voltage distribution.

20. The method of writing a non-volatile semiconductor memory device according to claim 16, wherein
the memory cell is configured to be able to store four-level data,
a plurality of the second threshold voltage distributions include three threshold voltage distributions, a plurality of the fourth threshold voltage distributions include three threshold voltage distributions,
the first threshold voltage distribution is allocated with one piece of data among of the four-level data,
the second threshold voltage distributions are allocated with the respective remaining pieces of data among of the four-level data, and
the method further comprises generating the highest threshold voltage distribution in the fourth threshold voltage distributions, based on the third threshold voltage distribution.
